(19) United States
(12) Patent Application Publication
(10) Pub. No.: US 2024/0244830 A1
(43) Pub. Date: Jul. 18, 2024

(54) SEMICONDUCTOR DEVICE

(71) Applicant: Samsung Electronics Co., Ltd., Suwon-si (KR)

(72) Inventors: Yoojin Jeong, Suwon-si (KR); Junghwan Huh, Suwon-si (KR)

(21) Appl. No.: 18/530,559

(22) Filed: Dec. 6, 2023

(30) Foreign Application Priority Data
Jan. 12, 2023 (KR) 10-2023-0004978

(51) Int. Cl. H10B 12/00

(52) U.S. Cl. CPC H10B 12/34; H10B 12/053; H10B 12/315

(57) ABSTRACT

A semiconductor device includes a substrate having an active region defined by an isolation layer, a word line crossing the active region and extending, within the substrate, in a first horizontal direction inside a word line trench, the word line trench being formed in the substrate and including a first sub word line trench and a second sub word line trench. A width, in the first horizontal direction, of a lower surface of the first sub word line trench is greater than a width, in the first horizontal direction, of a lower surface of the second sub word line trench, and a first distance between the lower surface of the first sub word line trench and an upper surface of the active region is less than a second distance between the lower surface of the second sub word line trench and the upper surface of the active region.

### CROSS-REFERENCE TO RELATED APPLICATION

This application is based on and claims priority under 35 U.S.C. § 119 to Korean Patent Application No. 10-2023-0004978, filed on Jan. 12, 2023, in the Korean Intellectual Property Office, the disclosure of which is incorporated by reference herein in its entirety.

### BACKGROUND

The inventive concept relates to a semiconductor device.

Electronic apparatuses are becoming more compact and lightweight according to rapid development of the electronics industry and demands of users. Accordingly, semiconductor devices having a high degree of integration are required in the electronic apparatuses, and thus, the sizes of features included the design rules for components of the semiconductor devices are decreasing.

### SUMMARY

The inventive concept provides a semiconductor device which exhibits a reduced process difficulty.

The objects of the inventive concept are not limited to the objects mentioned above, and other objects not described herein may be clearly understood by those skilled in the art from the following description.

The inventive concept provides a semiconductor device. In accordance with an aspect of the disclosure, a semiconductor device includes a substrate having an active region defined by an isolation layer; a word line crossing the active region and extending, within the substrate, in a first horizontal direction inside a word line trench, the word line trench being formed in the substrate and comprising a first sub word line trench and a second sub word line trench; and a bit line at a higher vertical level than a vertical level of the word line, the bit line extending in a second horizontal direction different from the first horizontal direction, wherein a width, in the first horizontal direction, of a lower surface of the first sub word line trench is greater than a width, in the first horizontal direction, of a lower surface of the second sub word line trench, and a first distance between the lower surface of the first sub word line trench and an upper surface of the active region that overlaps the word line in a vertical direction is less than a second distance between the lower surface of the second sub word line trench and the upper surface of the active region that overlaps the word line in the vertical direction.

The inventive concept provides a semiconductor device. In accordance with an aspect of the disclosure, a semiconductor device includes a substrate; an isolation layer which defines an active region inside the substrate, the isolation layer including a first isolation layer inside a first isolation trench and a second isolation layer inside a second isolation trench; a word line extending in a first horizontal direction inside a word line trench, the word line trench being formed in the substrate and comprising a first sub word line trench on the first isolation trench and a second sub word line trench on the second isolation trench; and a bit line at a higher vertical level than a vertical level of the word line and extends in a second horizontal direction perpendicular to the first horizontal direction, wherein a first width of the first isolation trench in the first horizontal direction is greater than a second width of the second isolation trench in the first horizontal direction, wherein the first isolation layer includes a first sub isolation layer and a second sub isolation layer on the first sub isolation layer, wherein the first sub isolation layer has a first thickness at a first vertical level and a second thickness at a second vertical level that is lower than the first vertical level, and wherein the second thickness is less than the first thickness. The inventive concept provides a semiconductor device. In accordance with an aspect of the disclosure, a semiconductor device includes a substrate having an active region defined by an isolation layer; a word line crossing the active region and extending, within the substrate, in a first horizontal direction inside a word line trench, the word line trench being formed in the substrate and comprising a first sub word line trench and a second sub word line trench; a bit line at a higher vertical level than a vertical level of the word line, the bit line extending in a second horizontal direction perpendicular to the first horizontal direction; a direct contact configured to electrically connect the bit line to the active region; a buried contact between bit lines; and a capacitor structure electrically connected to the active region via the buried contact, wherein a width, in the first horizontal direction, of a lower surface of the first sub word line trench is greater than a width, in the first horizontal direction, of a lower surface of the second sub word line trench, wherein a vertical level of the lower surface of the second sub word line trench is lower than a vertical level of the lower surface of the first sub word line trench, wherein the isolation layer includes a first isolation layer that overlaps, in a vertical direction, a first portion of the word line that is inside the first sub word line trench, wherein the first isolation layer includes a first sub isolation layer comprising an oxide and a second sub isolation layer on the first sub isolation layer, the second sub isolation layer comprising a nitride, wherein the first sub isolation layer has a first thickness at a first vertical level and a second thickness at a second vertical level that is lower than the first vertical level, and wherein the second thickness is less than the first thickness.

### BRIEF DESCRIPTION OF THE DRAWINGS

Embodiments will be more clearly understood from the following detailed description taken in conjunction with the accompanying drawings in which:

FIG. 1 is a schematic layout view of a semiconductor device according to embodiments of the inventive concept;

FIGS. 2A to 2D are cross-sectional views taken along lines A-A′, B-B′, C-C′, and D-D′ of FIG. 1;

FIG. 3 is an enlarged cross-sectional view of a semiconductor device according to embodiments of the inventive concept;

FIG. 4 is an enlarged cross-sectional view of a semiconductor device according to embodiments of the inventive concept; and

FIGS. 5A to 5F are cross-sectional views showing a method of manufacturing a semiconductor device, according to embodiments of the inventive concept.

### DETAILED DESCRIPTION OF THE EMBODIMENTS

Hereinafter, embodiments of the inventive concept are described in detail with reference to the accompanying drawings.

As used herein, a semiconductor device may refer, for example, to a device such as a semiconductor chip (e.g., memory chip and/or logic chip formed on a die).

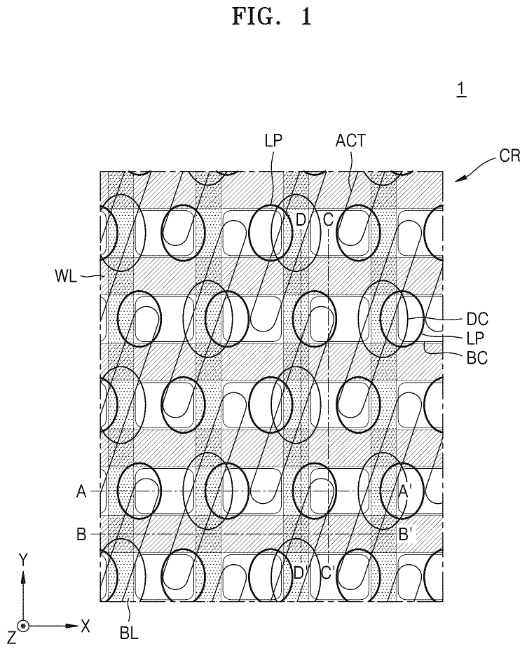

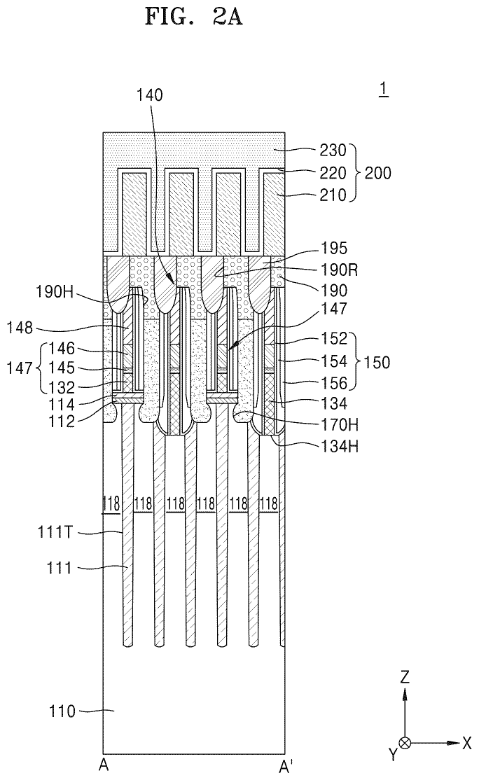

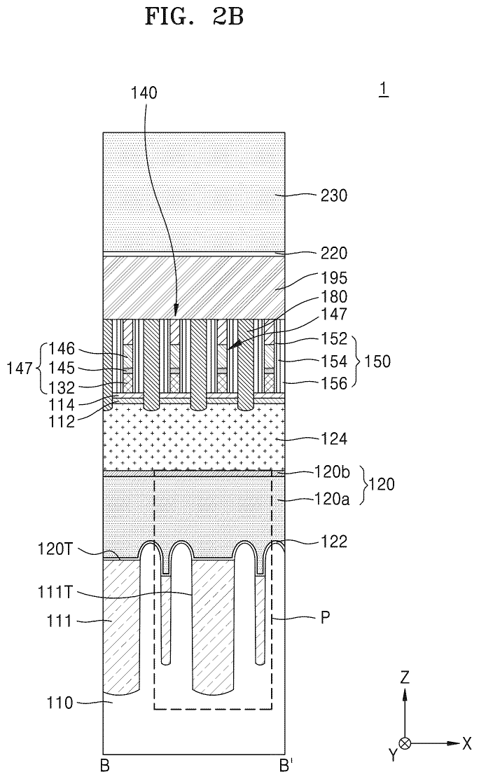

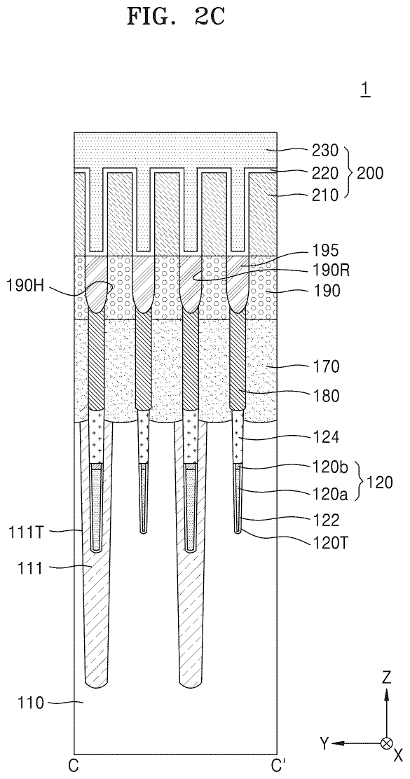

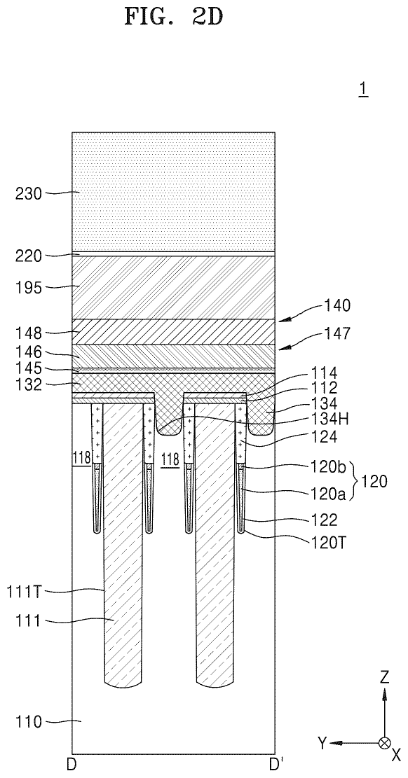

FIG. 1 is a schematic layout view of a semiconductor device according to embodiments of the inventive concept to describe main components thereof according to embodiments of the inventive concept. FIGS. 2A to 2D are cross-sectional views taken along lines A-A′, B-B′, C-C′, and D-D′, respectively, of FIG. 1.

Referring to FIG. 1, a semiconductor device 1 may include a plurality of active regions ACT formed in a memory cell region CR. In some embodiments, each of the plurality of active regions ACT arranged in the memory cell region CR may have a long axis in a direction inclined with respect to both a first horizontal direction (X direction) and a second horizontal direction (Y direction). The plurality of active regions ACT may constitute a plurality of active regions 118 illustrated in FIGS. 2A to 2D.

A plurality of word lines WL may extend parallel to each other in the first horizontal direction (X direction) across the plurality of active regions ACT. A plurality of bit lines BL may be provided on the plurality of word lines WL and extend parallel to each other in the second horizontal direction (Y direction) crossing the first horizontal direction (X direction).

In some embodiments, a plurality of buried contacts BC may be formed between two adjacent bit lines BL among the plurality of bit lines BL. In some embodiments, the plurality of buried contacts BC may be arranged in rows in each of the first horizontal direction (X direction) and the second horizontal direction (Y direction).

A plurality of landing pads LP may be respectively formed on the plurality of buried contacts BC. The plurality of landing pads LP may at least partially overlap the plurality of buried contacts BC. In some embodiments, each of the plurality of landing pads LP may extend to an upper portion of one of two adjacent bit lines BL.

A plurality of storage nodes may be respectively formed on the plurality of landing pads LP. A plurality of storage nodes may be formed on upper portions of the plurality of bit lines BL. The plurality of storage nodes may respectively include lower electrodes of a plurality of capacitors. The storage nodes may be connected to the active regions ACT via the landing pads LP and the buried contacts BC.

The semiconductor device 1 may include a dynamic random access memory (DRAM) device.

Referring to FIGS. 2A to 2D together, the semiconductor device 1 includes: a substrate 110 which includes a plurality of active regions 118 defined by an isolation layer 111 and has a plurality of word line trenches 120T crossing the plurality of active regions 118; a plurality of word lines 120 arranged respectively inside the plurality of word line trenches 120T; a plurality of bit line structures 140; and a plurality of capacitor structures 200 including a plurality of lower electrodes 210, a capacitor dielectric layer 220, and an upper electrode 230.

The substrate 110 may include and/or be formed of, for example, silicon (Si), crystalline Si, polycrystalline Si, or amorphous Si. In some embodiments, the substrate 110 may be formed of a crystalline semiconductor material, such as germanium (Ge), or may be formed of at least one compound semiconductor selected from silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may have a buried oxide (BOX) layer on which a layer of semiconductor material is formed (e.g., a semiconductor material described herein). The substrate 110 may include a conductive region, for example, a well doped with impurities or a structure doped with impurities.

The plurality of active regions 118 may include and/or be formed of a portion of the substrate 110 defined by an isolation trench 111T. The plurality of active regions 118 may have a relatively long island shape having short and long axes in a plan view. In some embodiments, each of the plurality of active regions 118 may have a long axis in a direction inclined with respect to both the first horizontal direction (X direction) and the second horizontal direction (Y direction). The plurality of active regions 118 may each extend with substantially the same length in the direction of the long axis, and may be repeatedly arranged with a substantially constant pitch.

The isolation layer 111 may fill the isolation trench 111T. The plurality of active regions 118 may be defined in the substrate 110 by the isolation layer 111.

In some embodiments, the isolation layer 111 may include and/or be formed of a single layer having one type of an insulating film, a double layer having two types of insulating films, a triple layer having three types of insulating films, or a multilayer having a combination of at least four types of insulating films. For example, the isolation layer 111 may include a single film made of a silicon oxide. In some embodiments, upper surfaces of the isolation layer 111 may have different vertical levels. A detailed description thereof is given below.

The plurality of word line trenches 120T may be formed in the substrate 110 that includes the plurality of active regions 118 defined by the isolation layer 111. The plurality of word line trenches 120T extend parallel to each other in the first horizontal direction (X direction) and each have a line shape crossing the active regions 118, and the word line trenches 120T may be arranged at substantially equal intervals in the second horizontal direction (Y direction) as shown, e.g., in FIGS. 2C and 2D. In some embodiments, a stepped portion may be formed on bottom surfaces of the plurality of word line trenches 120T. A specific shape of the plurality of word line trenches 120T is described below.

A plurality of gate dielectric films 122, a plurality of word lines 120, and a plurality of dummy buried insulating films 124 may be sequentially formed inside the plurality of word line trenches 120T. The plurality of word lines 120 may respectively constitute the plurality of word lines WL illustrated in FIG. 1. The plurality of word lines 120 extend parallel to each other in the first horizontal direction (X direction) and each have a line shape crossing the active regions 118, and the word lines 120 may be arranged at substantially equal intervals in the second horizontal direction (Y direction). The upper surface of each of the plurality of word lines 120 may be at a lower vertical level than a vertical level of the upper surface of the substrate 110. The bottom surfaces of the plurality of word lines 120 may have a concave-convex shape, and a saddle fin structure transistor (saddle FinFET) may be formed in the plurality of active regions 118.

The plurality of word lines 120 may respectively fill lower portions of the plurality of word line trenches 120T. Each of the plurality of word lines 120 may have a laminated structure of a lower word line layer 120a and an upper word line layer 120b. For example, the lower word line layer 120a may conformally cover the inner wall and bottom surface of the lower portion of each of the word line trenches 120T with a gate dielectric film 122 between the lower word line layer 120a and a wall of the respective word line trench 120T. For example, the upper word line layer 120b may cover the lower word line layer 120a and may fill a lower portion of the word line trench 120T with the gate dielectric film 122 between the upper word line layer 120b and a wall of the respective word line trench 120T. In some embodiments, the lower word line layer 120a may include a metal material, such as Ti, TiN, Ta, or TaN, or a conductive metal nitride. In some embodiments, the upper word line layer 120b may include, for example, doped polysilicon, a metal material, such as W, a conductive metal nitride, such as WN, TiSiN, WSiN, or a combination thereof.

On the active regions 118 of the substrate 110 on both sides of each of the plurality of word lines 120, a source region and a drain region formed by implanting impurity ions into the active regions 118 may be arranged.

The gate dielectric film 122 may cover the inner wall and bottom surface of the word line trench 120T. In some embodiments, the gate dielectric film 122 may extend from between the word line 120 and the wall of the word line trench 120T to between a dummy buried insulating film 124 and the word line trench 120T. The gate dielectric film 122 may include at least one selected from silicon oxide, silicon nitride, silicon oxynitride, oxide/nitride/oxide (ONO), and a high-k dielectric material having a higher dielectric constant than silicon oxide. For example, the gate dielectric film 122 may have a dielectric constant of about 10 to about 25. In some embodiments, the gate dielectric film 122 may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric film 122 may include HfO₂, Al₂O₃, HfAlO₃, Ta₂O₃, or TiO₂.

The plurality of dummy buried insulating films 124 may respectively fill upper portions of the plurality of word line trenches 120T. In some embodiments, the upper surfaces of the plurality of dummy buried insulating films 124 may be at substantially the same vertical level as the upper surface of the substrate 110 (see, e.g., FIG. 2D). The dummy buried insulating film 124 may include one material film selected from silicon oxide, silicon nitride, silicon oxynitride, and combinations thereof. For example, the dummy buried insulating film 124 may include silicon nitride.

Each of insulating film patterns 112 and 114 may be disposed on the isolation layer 111, the plurality of active regions 118, and the plurality of dummy buried insulating films 124. For example, the insulating film patterns 112 and 114 may include silicon oxide, silicon nitride, silicon oxynitride, a metal-based dielectric material, or a combination thereof. In some embodiments, the insulating film patterns 112 and 114 may have a laminated structure of a plurality of insulating films that include a first insulating film pattern and a second insulating film pattern and are hereinafter referred to as the first insulating film pattern and the second insulating film pattern. In some embodiments, the first insulating film pattern 112 may include silicon oxide, and the second insulating film pattern 114 may include silicon oxynitride. In some embodiments, the first insulating film pattern 112 may include a nonmetal-based dielectric material, and the second insulating film pattern 114 may include a metal-based dielectric material. In some embodiments, the second insulating film pattern 114 may be thicker than the first insulating film pattern 112. For example, the first insulating film pattern 112 may have a thickness of about 50 Å to about 90 Å. The second insulating film pattern 114 may be thicker than the first insulating film pattern 112 and have a thickness of about 60 Å to about 100 Å.

A plurality of direct contact conductive patterns 134 may fill portions of a plurality of direct contact holes 134H that pass through the insulating film patterns 112 and 114 and expose a source region inside the active regions 118. In some embodiments, the direct contact holes 134H may extend into the active regions 118, that is, into the source region. Each of the direct contact conductive patterns 134 may include, for example, doped polysilicon. In some embodiments, the direct contact conductive pattern 134 may include an epitaxial silicon layer. The plurality of direct contact conductive patterns 134 may respectively constitute a plurality of direct contacts DC illustrated in FIG. 1.

The plurality of bit line structures 140 may be arranged on the insulating film patterns 112 and 114. Each of the plurality of bit line structures 140 may include a bit line 147 (a conductor) and an insulating capping line 148 covering the bit line 147. The plurality of bit line structures 140 may extend parallel to each other in the second horizontal direction (Y direction) that is parallel to a main surface of the substrate 110. The plurality of bit lines 147 may respectively constitute the plurality of bit lines BL illustrated in FIG. 1. The plurality of bit lines 147 may be electrically connected to the plurality of active regions 118 via the plurality of direct contact conductive patterns 134. In some embodiments, each of the plurality of insulating capping lines 148 may include and/or be formed of a silicon nitride.

The bit line 147 may have a line-shaped stack structure of a first metal-based conductive pattern 145 and a second metal-based conductive pattern 146. In some embodiments, the first metal-based conductive pattern 145 may include titanium nitride (TiN) or TSN (Ti—Si—N), and the second metal-based conductive pattern 146 may include tungsten (W) and/or tungsten silicide (WSiₓ). In some embodiments, the first metal-based conductive pattern 145 may function as a diffusion barrier.

In some embodiments, the plurality of bit lines 147 may further include a conductive semiconductor pattern 132 located between the insulating film patterns 112 and 114 and the metal-based conductive patterns 145 and 146. The conductive semiconductor pattern 132 may include, for example, doped polysilicon.

A plurality of insulating spacer structures 150 may cover both side walls of the plurality of bit line structures 140. Each of the plurality of insulating spacer structures 150 may include a first insulating spacer 152, a second insulating spacer 154, and a third insulating spacer 156. In some embodiments, the plurality of insulating spacer structures 150 may extend into the plurality of direct contact holes 134H and cover both side walls of the plurality of direct contact conductive patterns 134 (see, e.g., FIG. 2A). The second insulating spacer 154 may include a material having lower permittivity than the first insulating spacer 152 and the third insulating spacer 156. In some embodiments, the first insulating spacer 152 and the third insulating spacer 156 may include nitride, and the second insulating spacer 154 may include oxide. In some embodiments, the first insulating spacer 152 and the third insulating spacer 156 include nitride, and the second insulating spacer 154 may include a material having an etch selectivity with respect to the first insulating spacer 152 and the third insulating spacer 156. For example, the first insulating spacer 152 and the third insulating spacer 156 may include nitride, and the second insulating spacer 154 may include an air spacer. In some embodiments, the insulating spacer structure 150 may include the second insulating spacer 154 including oxide and the third insulating spacer 156 including nitride.

Each of a plurality of insulating fences 180 may be located in a space between a pair of insulating spacer structures 150 facing each other between a pair of adjacent bit line structures 140 (see, e.g., FIG. 2B). The plurality of insulating spacer structures 150 may be spaced apart from each other and arranged in a row along between the pair of insulating spacer structures 150 facing each other, that is, in the second horizontal direction (Y direction). For example, the plurality of insulating fences 180 may include nitride.

In some embodiments, the plurality of insulating fences 180 may pass through the insulating film patterns 112 and 114 and extend into the dummy buried insulating film 124, but the invention is not limited thereto. In some embodiments, the plurality of insulating fences 180 may pass through the insulating film patterns 112 and 114 but not extend into the dummy buried insulating film 124, or may extend into the insulating film patterns 112 and 114 but not pass through the insulating film patterns 112 and 114. Also, the plurality of insulating fences 180 may be formed such that that lower surfaces thereof do not extend into the insulating film patterns 112 and 114 but are in contact with the insulating film patterns 112 and 114.

In each of spaces between the plurality of bit lines 147, a plurality of buried contact holes 170H may be defined between the plurality of insulating fences 180. The plurality of buried contact holes 170H and the plurality of insulating fences 180 may be alternately arranged along between a pair of insulating spacer structures 150 facing each other among the plurality of insulating spacer structures 150 covering both side walls of the plurality of bit line structures 140, that is, in the second horizontal direction (Y direction) as shown, e.g., in FIG. 2C. The inner space of each of the plurality of buried contact holes 170H may be defined by: the insulating spacer structure 150 covering the side wall of each of two neighboring bit lines 147 between the two neighboring bit lines 147 among the plurality of bit lines 147; the insulating fence 180; and the active region 118. In some embodiments, each of the plurality of buried contact holes 170H may extend into the active region 118 from between the insulating spacer structure 150 and the insulating fence 180.

A plurality of buried contacts 170 may be respectively arranged in the plurality of buried contact holes 170H. The plurality of buried contacts 170 may fill lower portions of spaces between the plurality of insulating spacer structures 150 that cover both side walls of each of the plurality of insulating fences 180 and the plurality of bit line structures 140. The plurality of buried contacts 170 and the plurality of insulating fences 180 may be alternately arranged along between a pair of insulating spacer structures 150 facing each other among the plurality of insulating spacer structures 150 covering both side walls of the plurality of bit line structures 140, that is, in the second horizontal direction (Y direction). For example, the plurality of buried contacts 170 may include polysilicon.

In some embodiments, the plurality of buried contacts 170 may be arranged in rows in each of the first horizontal direction (X direction) and the second horizontal direction (Y direction). Each of the plurality of buried contacts 170 may extend upward from the active region 118 in a vertical direction (Z direction) perpendicular to the substrate 110. The plurality of buried contacts 170 may respectively constitute the plurality of buried contacts BC illustrated in FIG. 1.

The level of the upper surfaces of the plurality of buried contacts 170 may be lower than the level of the upper surfaces of the plurality of insulating capping lines 148 (see, e.g., FIG. 2A). The upper surfaces of the plurality of insulating fences 180 and the upper surfaces of the plurality of insulating capping lines 148 may be at the same vertical level in the vertical direction (Z direction).

A plurality of landing pad holes 190H may be defined by the plurality of buried contacts 170, the plurality of insulating spacer structures 150, and the plurality of insulating fences 180 (see, e.g., FIGS. 2A and 2C). The plurality of buried contacts 170 may be exposed on the bottom surfaces of the plurality of landing pad holes 190H.

A plurality of landing pads 190 may fill at least a portion of the plurality of landing pad holes 190H and extend onto the plurality of bit line structures 140. The plurality of landing pads 190 may be separated from each other by a recess 190R. Each of the plurality of landing pads 190 may include a conductive barrier film and a conductive pad material layer on the conductive barrier film. For example, the conductive barrier film may include metal, conductive metal nitride, or a combination thereof. In some embodiments, the conductive barrier film may have a laminated structure of Ti/TiN. In some embodiments, the conductive pad material layer may include tungsten (W). In some embodiments, a metal silicide film may be formed between the landing pad 190 and the buried contact 170. The metal silicide film may include cobalt silicide (CoSix), nickel silicide (NiSix), or manganese silicide (MnSix), but the invention is not limited thereto.

The plurality of landing pads 190 are disposed on the plurality of buried contacts 170, and the plurality of buried contacts 170 and the plurality of landing pads 190, which correspond to each other, may be electrically connected to each other. The plurality of landing pads 190 may be respectively connected to the active regions 118 via the plurality of buried contacts 170. The plurality of landing pads 190 may respectively constitute the plurality of landing pads LP illustrated in FIG. 1. The buried contact 170 may be located between two adjacent bit line structures 140, and the landing pad 190 may extend onto one bit line structure 140 from between two bit line structures 140 adjacent to each other with the buried contact 170 therebetween. In other words, a portion of the landing pad 190 may be on the respective buried contact 170 and another portion of the landing pad 190 may be on the respective bit line structure 140.

The recess 190R may be filled with an insulating structure 195. In some embodiments, the insulating structure 195 may include an interlayer insulating layer and an etch stop film. For example, the interlayer insulating layer may include oxide, and the etch stop film may include nitride. For example, the etch stop film may include a silicon nitride film or silicon boron nitride (SiBN). FIGS. 2A and 2C illustrate that the upper surface of the insulating structure 195 and the upper surface of the plurality of landing pads 190 are at the same vertical level, but the invention is not limited thereto. For example, the insulating structure 195 may fill the recess 190R and may cover the upper surface of the plurality of landing pads 190 and may thus have the upper surface that is at a higher vertical level than the upper surface of the plurality of landing pads 190.

A plurality of capacitor structures 200, which include a plurality of lower electrodes 210, a capacitor dielectric layer 220, and an upper electrode 230, may be arranged on the plurality of landing pads 190 and the insulating structure 195. The lower electrode 210 and the landing pad 190, which correspond to each other, may be electrically connected to each other. FIGS. 2A and 2C illustrate that the upper surface of the insulating structure 195 and the lower surface of the lower electrode 210 are at the same vertical level, but the invention is not limited thereto.

In some embodiments, the semiconductor device 1 may further include at least one support pattern that is in contact with side walls of the plurality of lower electrodes 210 to support the plurality of lower electrodes 210. The at least one support pattern may include any one of a silicon nitride (SiN) film, a silicon carbonitride (SiCN) film, an N-rich silicon nitride (N-rich SiN) film, and an Si-rich silicon nitride (Si-rich SiN) film, but the invention is not limited thereto. In some embodiments, the at least one support pattern may include a plurality of support patterns which are in contact with the side walls of the plurality of lower electrodes 210 and at different vertical levels so that the support patterns are spaced apart from each other in the vertical direction (Z direction).

Each of the plurality of lower electrodes 210 may have a column shape, of which the inside is filled, that is, a pillar shape so as to have a circular horizontal cross-section, but the invention is not limited thereto. In some embodiments, each of the plurality of lower electrodes 210 may have a cylindrical shape with a lower portion closed. In some embodiments, the plurality of lower electrodes 210 may be arranged in zigzag in the first horizontal direction (X direction) or the second horizontal direction (Y direction) to form a honeycomb shape. In some embodiments, the plurality of lower electrodes 210 may be arranged in a row in each of the first horizontal direction (X direction) and the second horizontal direction (Y direction) to form a matrix shape. The plurality of lower electrodes 210 may include impurity-doped silicon, metal such as tungsten or copper, or a conductive metal compound such as titanium nitride. In some embodiments, the plurality of lower electrodes 210 may include TiN, CrN, VN, MON, NON, TiSiN, TiAlN, or TaAlN.

The capacitor dielectric layer 220 may conformally cover surfaces of the plurality of lower electrodes 210. In some embodiments, the capacitor dielectric layer 220 may be integrally formed to cover all the surfaces of the plurality of lower electrodes 210 together in a certain region, for example, in one memory cell region CR (FIG. 1).

The capacitor dielectric layer 220 may include a material having antiferroelectricity, a material having ferroelectricity, or a material having both antiferroelectricity and ferroelectricity. For example, the capacitor dielectric layer 220 may include silicon oxide, metal oxide, or a combination thereof. In some embodiments, the capacitor dielectric layer 220 may include a dielectric material including ABO₃ or MOₓ. For example, the capacitor dielectric layer 220 may include SiO, TaO, TaAIO, TaON, AIO, AISIO, HfO, HfSiO, ZrO, RuO, WO, HfZrO, ZrSiO, TiO, TiAIO, VO, NbO, MoO, MnO, LaO YO, CoO, NiO, CuO, ZnO, FeO, SrO, BaO, BST((Ba,Sr)TiO), STO(SrTiO), BTO(BaTiO), PTO(PbTiO), AgNbO, BiFeO, PZT(Pb(Zr,Ti)O), (Pb,La)(Zr,Ti)O, Ba(Zr, Ti)O, Sr(Zr,Ti)O, or a combination thereof.

The upper electrode 230 may be integrally formed above the plurality of lower electrodes 210 in a certain region, for example, in one memory cell region CR (FIG. 1). The plurality of lower electrodes 210, the capacitor dielectric layer 220, and the upper electrode 230 may constitute the plurality of capacitor structures 200 in a certain region, for example, in one memory cell region CR (FIG. 1).

The upper electrode 230 may include impurity-doped silicon, metal, such as tungsten or copper, or a conductive metal compound, such as titanium nitride. In some embodiments, the upper electrode 230 may include TiN, CrN, VN, MoN, NbN, TiSiN, TiAlN, or TaAlN. In some embodiments, the upper electrode 230 may have a laminated structure of at least two of a semiconductor material layer doped with impurities, a main electrode layer, and an interface layer. The doped semiconductor material layer may include, for example, doped polysilicon or doped polycrystalline silicon germanium (poly SiGe). The main electrode layer may include a metal material. The main electrode layer may include W, Ru, RuO, Pt, PtO, Ir, IrO, SRO(SrRuO), BSRO((Ba,Sr)RuO), CRO(CaRuO), BaRuO, La(Sr,Co)O, etc. In some embodiments, the main electrode layer may include W. The interface layer may include at least one of metal oxide, metal nitride, metal carbide, and metal silicide.

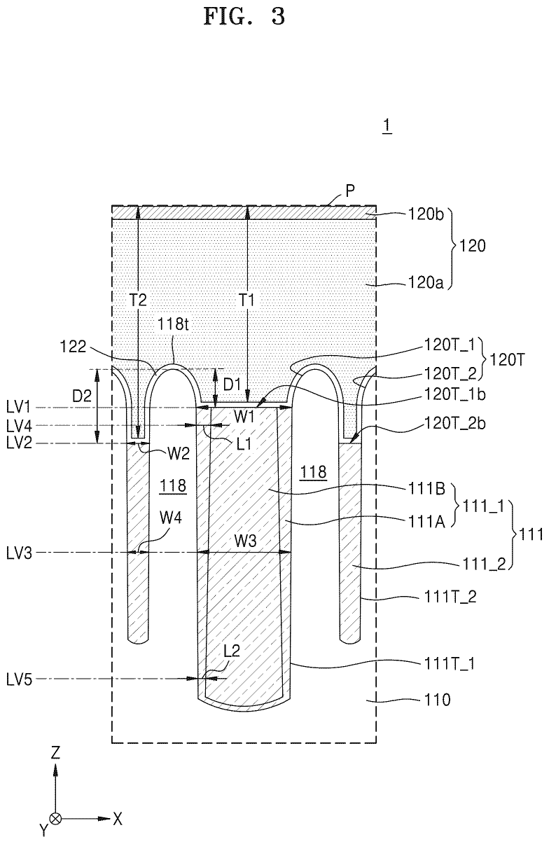

FIG. 3 is an enlarged cross-sectional view of the semiconductor device 1 according to embodiments of the inventive concept. Specifically, FIG. 3 is an enlarged cross-sectional view of region P of FIG. 2B.

Referring to FIG. 3, the word line trench 120T may include a first sub word line trench 120T_1 (e.g., a first trench portion) and a second sub word line trench 120T_2 (e.g., a second trench portion). Specifically, on the cross-section perpendicular to the second horizontal direction (Y direction), the first sub word line trench 120T_1 and the second sub word line trench 120T_2 may be connected to each other in the first horizontal direction (X direction) to constitute the word line trench 120T. For example, the first sub word line trench 120T_1 and the second sub word line trench 120T_2 may be alternately arranged. For example, the first sub word line trench 120T_1 may be located between a plurality of (e.g., two) second sub word line trenches 120T_2. For example, the second sub word line trench 120T_2 may be located between a plurality of (e.g., two) first sub word line trenches 120T_1.

In some embodiments, the first sub word line trench 120T_1 and the second sub word line trench 120T_2 may have different widths. Specifically, the width of the first sub word line trench 120T_1 in the first horizontal direction (X direction) may be greater than the width of the second sub word line trench 120T_2 in the first horizontal direction (X direction). For example, a width W1, in the first horizontal direction (X direction), of a lower surface 120T_1b of the first sub word line trench 120T_1 may be greater than a width W2, in the first horizontal direction (X direction), of a lower surface 120T_2b of the second sub word line trench 120T_2.

In some embodiments, the first sub word line trench 120T_1 and the second sub word line trench 120T_2 may have different depths. Specifically, the depth of the first sub word line trench 120T_1 in the vertical direction (Z direction) may be less than the depth of the second sub word line trench 120T_2 in the vertical direction (Z direction). For example, when an upper surface 118t of the active region 118 overlapping the word line 120 in the vertical direction (Z direction) is defined as an upper end of the word line trench 120T, the depth of the first sub word line trench 120T_1 in the vertical direction (Z direction) may be less than the depth of the second sub word line trench 120T_2 in the vertical direction (Z direction). That is, a first distance D1 between the lower surface 120T_1b of the first sub word line trench 120T_1 and the upper surface 118t of the active region 118 that overlaps the word line 120 in the vertical direction (Z direction) may be less than a second distance D2 between the lower surface 120T_2b of the second sub word line trench 120T_2 and the upper surface 118t of the active region 118.

In some embodiments, the lower surface 120T_1b of the first sub word line trench 120T_1 and the lower surface 120T_2b of the second sub word line trench 120T_2 may be at different vertical levels. Specifically, the lower surface 120T_1b of the first sub word line trench 120T_1 may be at a first vertical level LV1, and the lower surface 120T_2b of the second sub word line trench 120T_2 may be at a second vertical level LV2. In some embodiments, the lower surface 120T_1b of the first sub word line trench 120T_1 may be at a higher vertical level than the lower surface 120T_2b of the second sub word line trench 120T_2. That is, the first vertical level LV1 may be at a higher vertical level than the second vertical level LV2.

In some embodiments, the thickness of the word line 120 in the vertical direction (Z direction) above the first sub word line trench 120T_1 may be different from the thickness of the word line 120 in the vertical direction (Z direction) above the second sub word line trench 120T_2. Specifically, the word line 120 has a first vertical thickness T1 in the first sub word line trench 120T_1 and a second vertical thickness T2 in the second sub word line trench 120T_2. Here, the first vertical thickness T1 may be less than the second vertical thickness T2.

In some embodiments, the isolation layer 111 may include a first isolation layer 111_1 and a second isolation layer 111_2 that overlap the word line 120 in the vertical direction (Z direction). In some embodiments, the isolation trench 111T may include a first isolation trench 111T_1 and a second isolation trench 111T_2 that overlap the word line 120 in the vertical direction (Z direction). The first isolation layer 111_1 may be located inside the first isolation trench 111T_1. The second isolation layer 111_2 may be located inside the second isolation trench 111T_2.

In some embodiments, the first isolation layer 111_1 may overlap a first portion of the word line that is inside the first sub word line trench 120T_1 in the vertical direction (Z direction). The second isolation layer 111_2 may overlap a second portion of the word line that is inside the second sub word line trench 120T_2 in the vertical direction (Z direction).

In some embodiments, the first isolation layer 111_1 and the second isolation layer 111_2 may be alternately arranged in the first horizontal direction (X direction). Specifically, on the cross-section perpendicular to the second horizontal direction (Y direction) and passing through the word line 120, the first isolation layer 111_1 and the second isolation layer 111_2 may be alternately arranged in the first horizontal direction (X direction).

In some embodiments, the width of the first isolation trench 111T_1 in the first horizontal direction (X direction) and the width of the second isolation trench 111T_2 in the first horizontal direction (X direction) may be different from each other. Specifically, the width of the first isolation trench 111T_1 in the first horizontal direction (X direction) may be greater than the width of the second isolation trench 111T_2 in the first horizontal direction (X direction). Specifically, at the same vertical level, the width of the first isolation trench 111T_1 in the first horizontal direction (X direction) may be greater than the width of the second isolation trench 111T_2 in the first horizontal direction (X direction). For example, at a third vertical level LV3, a width W3 of the first isolation trench 111T_1 in the first horizontal direction (X direction) may be greater than a width W4 of the second isolation trench 111T_2 in the first horizontal direction (X direction).

In some embodiments, the first isolation layer 111_1 may include a first sub isolation layer 111A and a second sub isolation layer 111B on the first sub isolation layer 111A. In some embodiments, the first sub isolation layer 111A may conformally cover the inner and bottom surfaces of the first isolation trench 111T_1. In some embodiments, the second sub isolation layer 111B may fill the first isolation trench 111T_1 on the first sub isolation layer 111A. In some embodiments, the first sub isolation layer 111A may include an oxide (e.g., a first oxide) such as silicon oxide. In some embodiments, the second sub isolation layer 111B may include a nitride such as silicon nitride.

In some embodiments, thicknesses of the first sub isolation layer 111A in the first horizontal direction (X direction) may be different from each other at different vertical levels. In other words, the thickness of the first sub isolation layer 111A may gradually change in the vertical direction (Z direction). Specifically, the thickness of the first sub isolation layer 111A in the first horizontal direction (X direction) may be greater at a higher vertical level than at a lower vertical level. For example, a first thickness L1 of the first sub isolation layer 111A at a fourth vertical level LV4 may be greater than a second thickness L2 of the first sub isolation layer 111A at a fifth vertical level LV5 that is lower than the fourth vertical level LV4.

In some embodiments, thicknesses of the second sub isolation layer 111B in the first horizontal direction (X direction) may be different from each other at different vertical levels. Specifically, the thickness of the second sub isolation layer 111B in the first horizontal direction (X direction) may be greater at a lower vertical level than at a higher vertical level.

In some embodiments, the thickness of the first sub isolation layer 111A in the first horizontal direction (X direction) may increase from a lower vertical level to a higher vertical level. For example, the thickness of the first sub isolation layer 111A in the first horizontal direction (X direction) may continuously increase from a lower vertical level to a higher vertical level.

In some embodiments, the second isolation layer 111_2 may include the same material as or a different material from that of the first sub isolation layer 111A. For example, the second isolation layer 111_2 may include an oxide (e.g., a second oxide) such as silicon oxide.

In some embodiments, half of the width W4 of the second isolation trench 111T_2 in the first horizontal direction (X direction) may be greater than or equal to the second thickness L2 of the first sub isolation layer 111A at the fifth vertical level LV5 and may be less than or equal to the first thickness L1 of the first sub isolation layer 111A at the fourth vertical level LV4. In some embodiments, the half of the width W4 of the second isolation trench 111T_2 in the first horizontal direction (X direction) may be equal to the average of the second thickness L2 of the first sub isolation layer 111A at the fifth vertical level LV5 and the first thickness L1 of the first sub isolation layer 111A at the fourth vertical level LV4.

In some embodiments, the upper surface of the second isolation layer 111_2 may be at a lower vertical level than the upper surface of the first isolation layer 111_1. Specifically, the upper surface of the second isolation layer 111_2 overlapping the word line 120 in the vertical direction (Z direction) may be at a lower vertical level than the upper surface of the first isolation layer 111_1 overlapping the word line 120 in the vertical direction (Z direction). For example, the upper surface of the second isolation layer 111_2 overlapping the word line 120 in the vertical direction (Z direction) may be at a lower vertical level than the upper surface of the first sub isolation layer 111A overlapping the word line 120 in the vertical direction (Z direction). For example, the upper surface of the second isolation layer 111_2 overlapping the word line 120 in the vertical direction (Z direction) may be at a lower vertical level than the upper surface of the second sub isolation layer 111B overlapping the word line 120 in the vertical direction (Z direction).

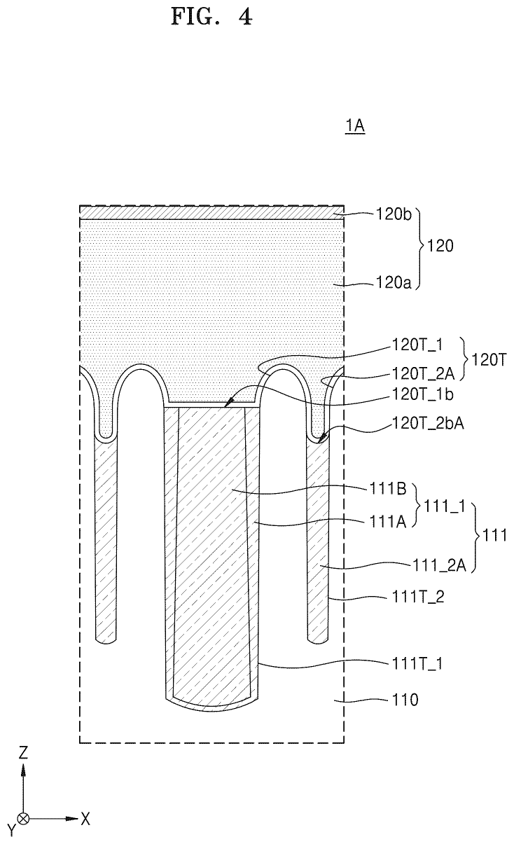

FIG. 4 is an enlarged cross-sectional view of a semiconductor device 1A according to some embodiments of the inventive concept. Specifically, FIG. 4 is an enlarged cross-sectional view corresponding to region P of FIG. 2B.

Referring to FIG. 3, a word line trench 120T may include a first sub word line trench 120T_1 and a second sub word line trench 120T_2A. Unlike the semiconductor device 1 described with reference to FIG. 3, the second sub word line trench 120T_2A of the semiconductor device 1A as shown, e.g., in FIG. 4 may have a V-shaped or U-shaped cross-section. Specifically, on the cross-section perpendicular to a second horizontal direction (Y direction), the second sub word line trench 120T_2A may have a V-shaped or U-shaped cross-section. That is, the vertical level of a lower surface 120T_2bA of the second sub word line trench 120T_2A may not be constant in a first horizontal direction (X direction). For example, the vertical level of the lower surface 120T_2bA of the second sub word line trench 120T_2A may decrease and then increase in the first horizontal direction (X direction). For example, the lower surface 120T_2bA of the second sub word line trench 120T_2A may have the highest vertical level at the boundary with a substrate 110. For example, the lower surface 120T_2bA of the second sub word line trench 120T_2A may have the lowest vertical level in a region that is not in contact with the substrate 110. In some embodiments, the vertical level of the lower surface 120T_2bA of the second sub word line trench 120T_2A may be lower than the vertical level of a lower surface 120T_1b of the first sub word line trench 120T_1.

In some embodiments, an isolation layer 111 may include a first isolation layer 111_1 and a second isolation layer 111_2A that both overlap a word line 120 in the vertical direction (Z direction). Specifically, on the cross-section perpendicular to the second horizontal direction (Y direction) and passing through the word line 120, the second isolation layer 111_2A may have a V-shaped or U-shaped cross-section. That is, the vertical level of the upper surface of the second isolation layer 111_2A may not be constant in the first horizontal direction (X direction). For example, the vertical level of the upper surface of the second isolation layer 111_2A may decrease and then increase in the first horizontal direction (X direction). For example, the upper surface of the second isolation layer 111_2A may have the highest vertical level at the boundary with the substrate 110. For example, the upper surface of the second isolation layer 111_2A may have the lowest vertical level in a region that is not in contact with the substrate 110.

In some embodiments, the lowest vertical level of the upper surface of the second isolation layer 111_2A may be lower than the vertical level of the upper surface of the first isolation layer 111_1. In some embodiments, the lowest vertical level of the upper surface of the second isolation layer 111_2A may be lower than the vertical level of the upper surface of a first sub isolation layer 111A. In some embodiments, the lowest vertical level of the upper surface of the second isolation layer 111_2A may be lower than the vertical level of the upper surface of a second sub isolation layer 111B.

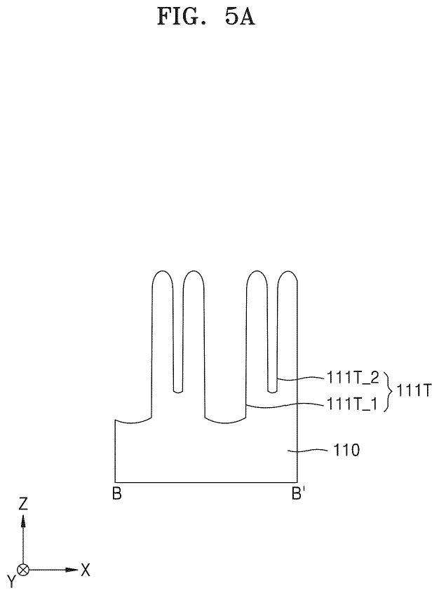

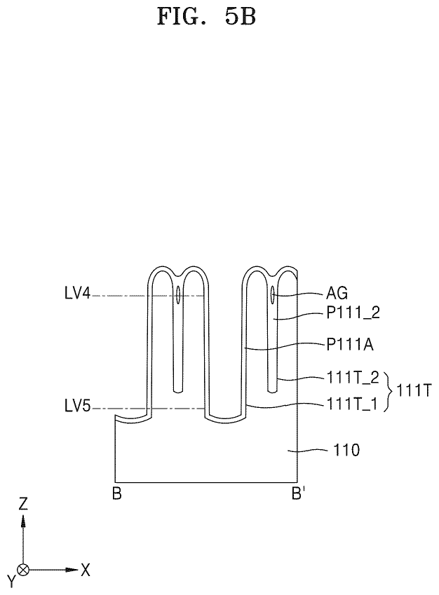

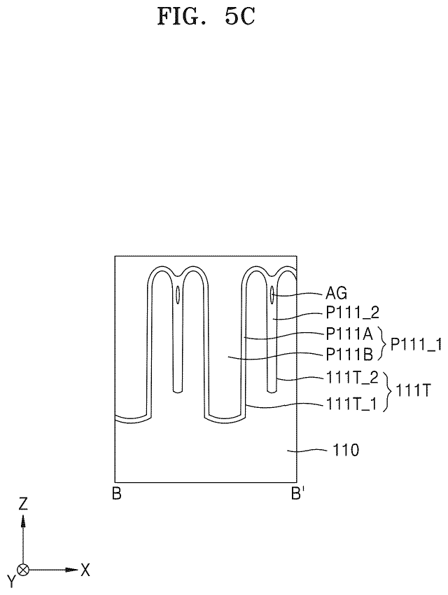

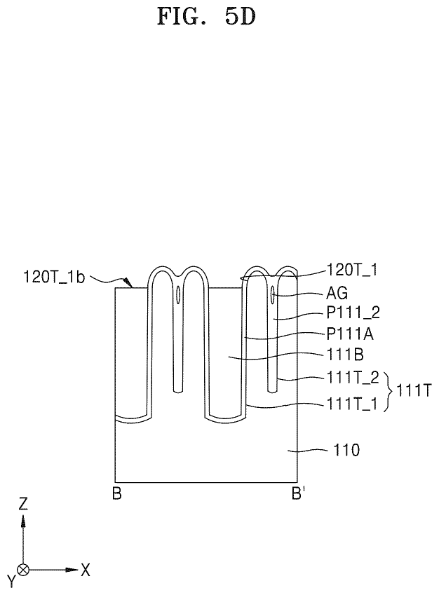

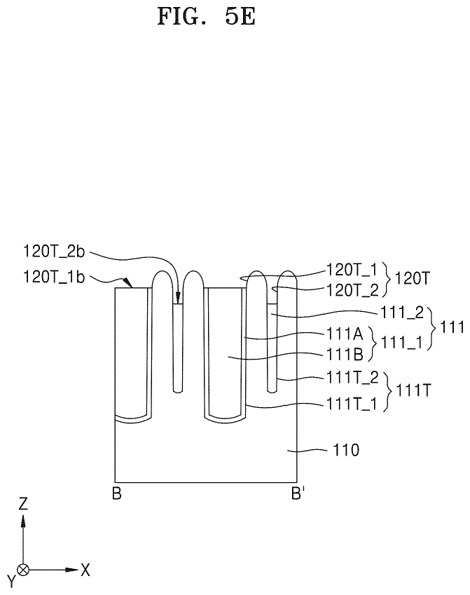

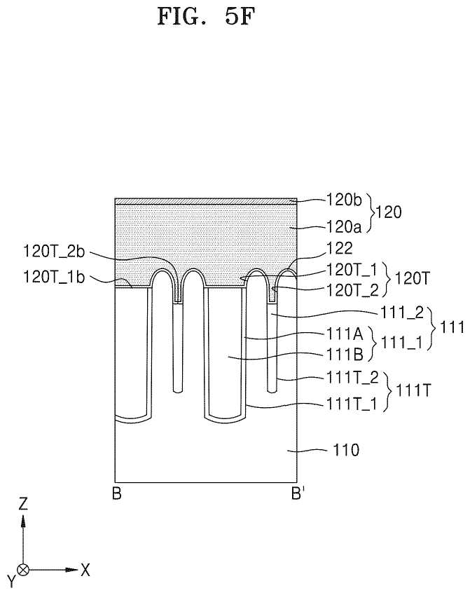

FIGS. 5A to 5F are cross-sectional views showing a method of manufacturing a semiconductor device 1, according to embodiments of the inventive concept. Specifically, FIGS. 5A to 5F are cross-sectional views showing a method of manufacturing the semiconductor device 1 illustrated as an example in FIG. 3.

Referring to FIG. 5A, a substrate 110 may be patterned. Specifically, an isolation trench 111T may be formed by patterning the substrate 110. Specifically, the substrate 110 may be patterned to form a first isolation trench 111T_1 and a second isolation trench 111T_2. In some embodiments, the width of the first isolation trench 111T_1 in a first horizontal direction (X direction) may be greater than the width of the second isolation trench 111T_2 in the first horizontal direction (X direction). In some embodiments, the vertical depth of the first isolation trench 111T_1 may be greater than the vertical depth of the second isolation trench 111T_2.

Referring to FIG. 5B, a pre-first sub isolation layer P111A may be formed to conformally cover inner and bottom surfaces of the first isolation trench 111T_1, and a pre-second isolation layer P111_2 may be formed to partially fill the second isolation trench 111T_2. Specifically, silicon oxide may be applied on the first isolation trench 111T_1 to form the pre-first sub isolation layer P111A that conformally covers the inner and bottom surfaces of the first isolation trench 111T_1. Specifically, silicon oxide is applied on the second isolation trench 111T_2 to form the pre-second isolation layer P111_2, which partially fills the second isolation trench 111T_2, and an air gap AG, which is present in the middle of the pre-second isolation layer P111_2.

In some embodiments, the process of applying the silicon oxide on the first isolation trench 111T_1 and the second isolation trench 111T_2 may include a chemical vapor deposition (CVD) process, a plasma-enhanced chemical vapor deposition (PECVD) process, a metal organic CVD (MOCVD) process, or an atomic layer deposition (ALD) process. For example, the process of applying the silicon oxide on the first isolation trench 111T_1 and the second isolation trench 111T_2 may include an ALD process in which a step coverage is adjusted. For example, the silicon oxide may be applied on the first isolation trench 111T_1 and the second isolation trench 111T_2 by using an ALD process in which the step coverage is lowered by adjusting pressure, temperature, and the like.

In some embodiments, the thicknesses, in the first horizontal direction (X direction), of the pre-first sub isolation layer P111A conformally covering the inner and bottom surfaces of the first isolation trench 111T_1 may be different from each other at different vertical levels. Specifically, the thickness of the pre-first sub isolation layer P111A in the first horizontal direction (X direction) may be greater at a higher vertical level than at a lower vertical level. For example, the thickness of the pre-first sub isolation layer P111A in the first horizontal direction (X direction) may be greater at a fourth vertical level LV4 than at a fifth vertical level LV5 that is lower than the fourth vertical level LV4. This may be caused by the ALD process in which the step coverage is lowered. Due to the low step coverage, the thickness in the first horizontal direction (X direction) at a higher vertical level (e.g., the fourth vertical level LV4) close to an opening of the first isolation trench 111T_1 may be greater than the thickness at a lower vertical level (e.g., the fifth vertical level LV5) close to the bottom surface of the first isolation trench 111T_1.

In some embodiments, the pre-second isolation layer P111_2 may not completely fill the second isolation trench 111T_2. That is, the air gap AG may be formed in a space in which the pre-second isolation layer P111_2 is not formed. This may be caused by the ALD process in which the step coverage is lowered. Due to the low step coverage, the air gap AG may be formed as a film material is accumulated first near the opening in the second isolation trench 111T_2 having a smaller width than the first isolation trench 111T_1.

It should be appreciated that an “air gap” may comprise a gap having air or other gases (e.g., such as those present during manufacturing) or may comprise a gap forming a vacuum therein.

Referring to FIG. 5C, a pre-second sub isolation layer P111B may be formed to completely fill the first isolation trench 111T_1. In some embodiments, the pre-second sub isolation layer P111B may include silicon nitride. In some embodiments, the process of forming the pre-second sub isolation layer P111B may include a CVD process, a PECVD process, an MOCVD process, or an ALD process.

Referring to FIG. 5D, the pre-second sub isolation layer P111B may be partially etched to form the second sub isolation layer 111B. In some embodiments, the upper surface of the second sub isolation layer 111B may form a portion of a lower surface 120T_1b of a first sub word line trench 120T_1.

In some embodiments, while the pre-second sub isolation layer P111B is partially etched, the pre-first sub isolation layer P111A and the pre-second isolation layer P111_2 may not be etched. In some embodiments, the pre-second sub isolation layer P111B may be partially etched to expose the pre-first sub isolation layer P111A and the pre-second isolation layer P111_2. In some embodiments, while the pre-second sub isolation layer P111B is partially etched, the air gap AG may not be exposed.

In some embodiments, the vertical level of the upper surface of the second sub isolation layer 111B may be lower than the vertical level of the uppermost portion of the air gap AG and may be higher than the vertical level of the lowermost portion of the air gap AG. However, the inventive concept is not limited thereto.

Referring to FIG. 5E, the pre-first sub isolation layer P111A and the pre-second isolation layer P111_2 may be etched to form a first sub isolation layer 111A and a second isolation layer 111_2, respectively. That is, the first isolation layer 111_1 and the second isolation layer 111_2 may be formed. Accordingly, a second sub word line trench 120T_2 may be formed.

In some embodiments, the upper surface of the second isolation layer 111_2 may form a lower surface 120T_2b of the second sub word line trench 120T_2. In some embodiments, the upper surface of the first sub isolation layer 111A may be at the same vertical level as that of the second sub isolation layer 111B. In some embodiments, the upper surface of the first sub isolation layer 111A and the upper surface of the second sub isolation layer 111B may form the lower surface 120T_1b of the first sub word line trench 120T_1. In some embodiments, the vertical level of the upper surface of the first sub isolation layer 111A may not be constant, and the vertical level of a portion of the upper surface of the first sub isolation layer 111A may not be the same as that of the second sub isolation layer 111B.

In some embodiments, the process of forming the second isolation layer 111_2 by etching the pre-second isolation layer P111_2 may use the air gap AG of FIG. 5D. In general, when the same etching process is used, the etching rate of the pre-second isolation layer P111_2 in a vertical direction (Z direction) may be similar to or less than the etching rate of the pre-first sub isolation layer P111A in the vertical direction (Z direction). However, in the process described above according to the inventive concept, the air gap AG is formed in the middle of the pre-second isolation layer P111_2. Accordingly, when the pre-second isolation layer P111_2 is etched to the vertical level of the uppermost portion of the air gap AG, an effect in which the etching is performed to the vertical level of the lowermost portion of the air gap AG may be obtained. That is, it is possible to obtain the second isolation layer 111_2 that has the upper surface at a vertical level lower than that of the upper surface of the first isolation layer 111_1. In particular, when the vertical level of the lowermost portion of the air gap AG is lower than the vertical level of the upper surface of the second sub isolation layer 111B, it is possible to obtain the second isolation layer 111_2 that has the upper surface at a vertical level lower than that of the upper surface of the second sub isolation layer 111B.

Referring to FIG. 5F, a gate dielectric film 122 and a word line 120 are sequentially formed inside a word line trench 120T, e.g., inside the first sub word line trench 120T_1 and the second sub word line trench 120T_2, and accordingly, the semiconductor device 1 may be formed. A method of manufacturing the semiconductor device 1, which exhibits a reduced process difficulty, has been described with reference to FIGS. 5A to 5F.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate having an active region defined by an isolation layer;
a word line crossing the active region and extending, within the substrate, in a first horizontal direction inside a word line trench, the word line trench being formed in the substrate and comprising a first sub word line trench and a second sub word line trench; and
a bit line at a higher vertical level than a vertical level of the word line, the bit line extending in a second horizontal direction different from the first horizontal direction,
wherein a width, in the first horizontal direction, of a lower surface of the first sub word line trench is greater than a width, in the first horizontal direction, of a lower surface of the second sub word line trench, and
a first distance between the lower surface of the first sub word line trench and an upper surface of the active region that overlaps the word line in a vertical direction is less than a second distance between the lower surface of the second sub word line trench and the upper surface of the active region that overlaps the word line in the vertical direction.

2. The semiconductor device of claim 1, wherein the isolation layer comprises:
a first isolation layer that overlaps, in the vertical direction, a first portion of the word line that is inside the first sub word line trench; and
a second isolation layer that overlaps, in the vertical direction, a second portion of the word line that is inside the second sub word line trench,
wherein a width, in the first horizontal direction, of a first isolation trench in which the first isolation layer is located is greater than a width, in the first horizontal direction, of a second isolation trench in which the second isolation layer is located.

3. The semiconductor device of claim 2, wherein the first isolation layer comprises a first sub isolation layer and a second sub isolation layer on the first sub isolation layer.

4. The semiconductor device of claim 3, wherein the second isolation layer comprises the same material as a material of the first sub isolation layer.

5. The semiconductor device of claim 3, wherein the first sub isolation layer has a first thickness in the first horizontal direction at a first vertical level and has a second thickness in the first horizontal direction at a second vertical level which is lower than the first vertical level, and
wherein the second thickness is less than the first thickness.

6. The semiconductor device of claim 1, wherein the word line has a first vertical thickness inside the first sub word line trench and has a second vertical thickness inside the second sub word line trench, and
wherein the first vertical thickness is less than the second vertical thickness.

7. A semiconductor device comprising:
a substrate;
an isolation layer which defines an active region inside the substrate, the isolation layer comprising a first isolation layer inside a first isolation trench and a second isolation layer inside a second isolation trench;
a word line extending in a first horizontal direction inside a word line trench, the word line trench being formed in the substrate and comprising a first sub word line trench on the first isolation trench and a second sub word line trench on the second isolation trench; and
a bit line at a higher vertical level than a vertical level of the word line and extends in a second horizontal direction perpendicular to the first horizontal direction,
wherein a first width of the first isolation trench in the first horizontal direction is greater than a second width of the second isolation trench in the first horizontal direction,
wherein the first isolation layer comprises a first sub isolation layer and a second sub isolation layer on the first sub isolation layer,
wherein the first sub isolation layer has a first thickness at a first vertical level and a second thickness at a second vertical level that is lower than the first vertical level, and
wherein the second thickness is less than the first thickness.

8. The semiconductor device of claim 7, wherein a vertical level of a lower surface of the second sub word line trench is lower than a vertical level of a lower surface of the first sub word line trench.

9. The semiconductor device of claim 7, wherein a width, in the first horizontal direction, of a lower surface of the first sub word line trench is greater than a width, in the first horizontal direction, of a lower surface of the second sub word line trench.

10. The semiconductor device of claim 7, wherein a first portion of the word line has a first vertical thickness inside the first sub word line trench and a second portion of the word line has a second vertical thickness inside the second sub word line trench, and
wherein the first vertical thickness is less than the second vertical thickness.

11. The semiconductor device of claim 7, wherein half of the second width of the second isolation trench in the first horizontal direction is greater than or equal to the second thickness of the first sub isolation layer at the second vertical level, and
wherein half of the second width of the second isolation trench in the first horizontal direction is less than or equal to the first thickness of the first sub isolation layer at the first vertical level.

12. The semiconductor device of claim 7, wherein the first sub isolation layer comprises a first oxide, the second sub isolation layer comprises a nitride, and the second isolation layer comprises a second oxide.

13. The semiconductor device of claim 7, wherein the first isolation layer and the second isolation layer overlap the word line in a vertical direction.

14. A semiconductor device comprising:
a substrate having an active region defined by an isolation layer;
a word line crossing the active region and extending, within the substrate, in a first horizontal direction inside a word line trench, the word line trench being formed in the substrate and comprising a first sub word line trench and a second sub word line trench;
a bit line at a higher vertical level than a vertical level of the word line, the bit line extending in a second horizontal direction perpendicular to the first horizontal direction;
a direct contact configured to electrically connect the bit line to the active region;
a buried contact between bit lines; and
a capacitor structure electrically connected to the active region via the buried contact,
wherein a width, in the first horizontal direction, of a lower surface of the first sub word line trench is greater than a width, in the first horizontal direction, of a lower surface of the second sub word line trench,
wherein a vertical level of the lower surface of the second sub word line trench is lower than a vertical level of the lower surface of the first sub word line trench,
wherein the isolation layer comprises a first isolation layer that overlaps, in a vertical direction, a first portion of the word line that is inside the first sub word line trench,
wherein the first isolation layer comprises a first sub isolation layer comprising an oxide and a second sub isolation layer on the first sub isolation layer, the second sub isolation layer comprising a nitride,
wherein the first sub isolation layer has a first thickness at a first vertical level and a second thickness at a second vertical level that is lower than the first vertical level, and
wherein the second thickness is less than the first thickness.

15. The semiconductor device of claim 14, wherein the isolation layer further comprises a second isolation layer that overlaps, in the vertical direction, a second portion of the word line that is inside the second sub word line trench, and
wherein a width, in the first horizontal direction, of a first isolation trench in which the first isolation layer is located is greater than a width, in the first horizontal direction, of a second isolation trench in which the second isolation layer is located.

16. The semiconductor device of claim 15, wherein an upper surface of the second isolation layer is at a lower vertical level than a vertical level of an upper surface of the second sub isolation layer.

17. The semiconductor device of claim 15, wherein the first isolation layer and the second isolation layer are alternately arranged in the first horizontal direction.

18. The semiconductor device of claim 15, wherein an upper surface of the second isolation layer has a cross-section having at least one of a V-shape and a U-shape, and
wherein a lowest vertical level of the upper surface of the second isolation layer is lower than a vertical level of an upper surface of the first sub isolation layer.

19. The semiconductor device of claim 14, wherein the first portion of the word line has a first vertical thickness and a second portion of the word line that is inside the second sub word line trench has a second vertical thickness, and
wherein the first vertical thickness is less than the second vertical thickness.

20. The semiconductor device of claim 14, wherein a first distance between the lower surface of the first sub word line trench and an upper surface of the active region that overlaps the word line in the vertical direction is less than a second distance between the lower surface of the second sub word line trench and the upper surface of the active region that overlaps the word line in the vertical direction.
